(19) United States
(12) Patent Application Publication
(10) Pub. No.: US 2009/0136874 A1
(43) Pub. Date: May 28, 2009

(54) Method for manufacturing printed circuit board

(75) Inventors: In-Young KIM, Suwon-si (KR); Jae-Woo JOUNG, Suwon-si (KR); Hyun-Chul JUNG, Yongin-si (KR); Young-Ah SONG, Suwon-si (KR); Young-Seuck YOO, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/149,750

(22) Filed: May 7, 2008

(30) Foreign Application Priority Data
Nov. 23, 2007 (KR) 10-2007-0120529

(51) Int. Cl. G03F 7/26

(52) U.S. Cl. 430/311

(57) ABSTRACT

A method of manufacturing a printed circuit board is disclosed. The method, which includes forming a base pattern over one side of a negative photoresist, exposing the one side, attaching an insulation layer on the one side, developing the negative photoresist such that the base pattern is uncovered, and forming a circuit pattern over the base pattern, can increase the thickness of the circuit pattern and strengthen the adhesion between the circuit pattern and the insulation layer.

### CROSS-REFERENCE TO RELATED APPLICATIONS

This application claims the benefit of Korean Patent Application No. 10-2007-0120529 filed with the Korean Intellectual Property Office on Nov. 23, 2007, the disclosure of which is incorporated herein by reference in its entirety.

### BACKGROUND

1. Technical Field

The present invention relates to a method for manufacturing a printed circuit board.

2. Description of the Related Art

The inkjet method, of fabricating a circuit board by printing metal wiring, is currently receiving much attention. When using the inkjet method, there is no need to create a photomask, such as that used for lithography processes, and as only the required images as stored in the form of software have to be printed using metal ink, fine-lined patterns may be implemented without expending excess materials. As such, the inkjet method provides numerous advantages in terms of conserving energy, lowering costs, and providing multiple layers and thinner products, etc. With the application of the inkjet method, it is expected that the embedding of inductors and capacitors, etc., will be viable with relatively low costs, and there are also favorable predictions with regard to application in high-frequency oscillation circuits.

When the resolution for inkjet printing is increased, it is possible to form a satisfactory wiring pattern from CAD data without the use of a mask. In contrast to the equipment for photolithography processes, in which a plethora of complicated chemical treatments are required, the equipment required for inkjet processes may be very simple, sometimes consisting only of an inkjet device and a curing oven, with the greater part of the manufacture of the circuit board occurring inside a computer. Whereas most printing processes require masks, a significant advantage of inkjet printing is that it is maskless. As design changes may be effected immediately on a substrate; inkjet printing is expected to be utilized in tools for developing circuit designs.

In forming metal wiring, one droplet of ink may have a volume of several to several tens of picoliters. Thus, metal wiring is formed by connecting the minute droplets of ink, the size of which lies in the scale of several tens of micrometers. As such, while it is easy to implement fine-lined wiring, the thickness of the wiring may be considerably thinner compared to typical board wiring.

However, since sheet resistance is higher increased when the thickness of the wiring is decreased, fine-lined wiring requires a certain level of thickness. Also, as the metal particles within an ink are made to display the desired electrical and mechanical properties after sintering, the adhesion between the metal wiring and the substrate after sintering is an important factor that determines the reliability of the product.

While there is currently no definite process established for manufacturing a board using inkjet printing, the most basic procedures include first printing ink on a completely cured polymer substrate and then subjecting the substrate to sintering. However, the results of manufacturing a board by this method have as yet provided very low adhesion between the substrate and the metal wiring.

One example of increasing the thickness of wiring formed by an inkjet method may include repeated printing. However, repeated printing can result in large tolerances in the width of the wiring, due to deviations in the alignment of the equipment. Also, since bulges may occur when liquid ink is printed continuously, the printing algorithm has to be implemented with careful attention. Other difficulties may include having to heat the stage before printing.

### SUMMARY

An aspect of the invention provides a method for manufacturing a printed circuit board that can increase the thickness of the circuit pattern and strengthen the adhesion between the circuit pattern and the insulation layer.

Another aspect of the invention provides a method for manufacturing a printed circuit board which includes forming a base pattern over one side of a negative photoresist, exposing the one side, attaching an insulation layer on the one side, developing the negative photoresist such that the base pattern is uncovered, and forming a circuit pattern over the base pattern.

Here, the forming of the base pattern can include ejecting conductive ink over the one side to form the base pattern.

The insulation layer may contain polyester or polyimide.

The operation of attaching the insulation layer can include stacking a semi-cured thermosetting resin over the one side, and hot-pressing the thermosetting resin and the negative photoresist.

The forming of the circuit pattern can include ejecting conductive ink over the base pattern to form the circuit pattern.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method for manufacturing a printed circuit board according to an embodiment of the invention.

FIG. 2, FIG. 3, FIG. 4, FIG. 5, FIG. 6, FIG. 7, FIG. 8, and FIG. 9 are cross-sectional views representing a method for manufacturing a printed circuit board according to an embodiment of the invention.

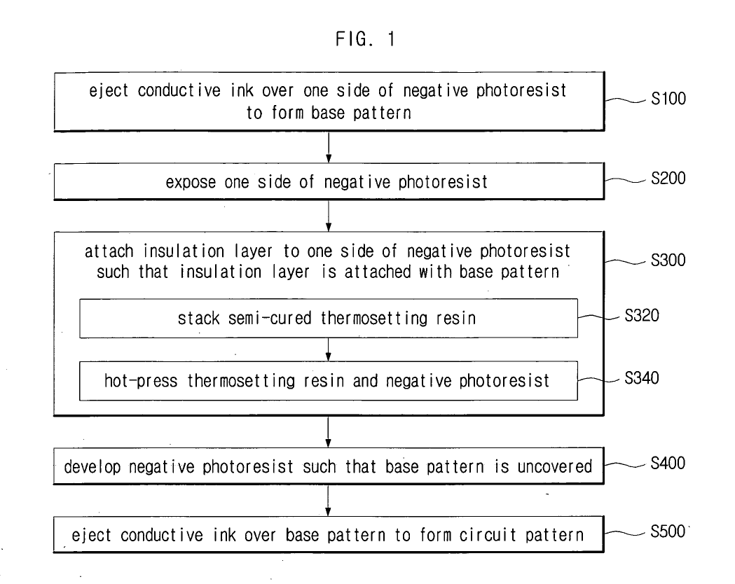

### DETAILED DESCRIPTION

The method for manufacturing a printed circuit board according to certain embodiments of the invention will be described below in more detail with reference to the accompanying drawings. Those components that are the same or are in correspondence are rendered the same reference numeral regardless of the figure number, and redundant explanations are omitted.

A method for manufacturing a printed circuit board according to an embodiment of the invention may include forming a base pattern over one side of a negative photoresist, exposing the one side, attaching an insulation layer on the one side, developing the negative photoresist such that the base pattern is uncovered, and forming a circuit pattern over the base pattern. This method can increase the thickness of the circuit pattern and strengthen the adhesion between the circuit pattern and the insulation layer.

To manufacture a printed circuit board, first, a conductive ink may be ejected onto one side of a negative photoresist to form a base pattern (S100).

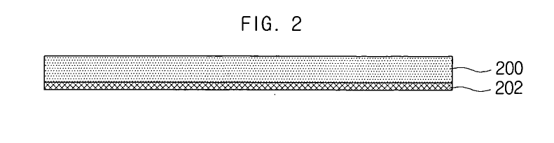

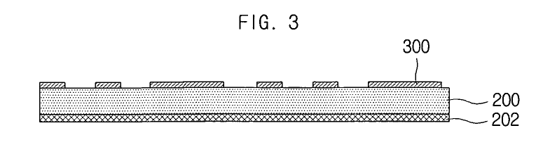

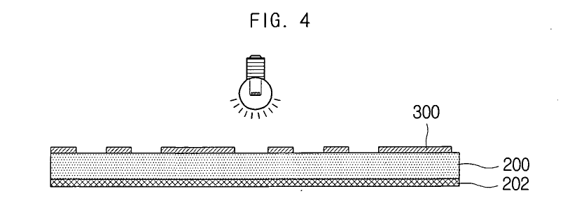

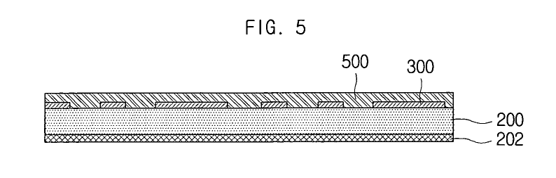

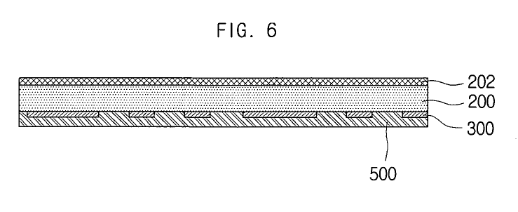

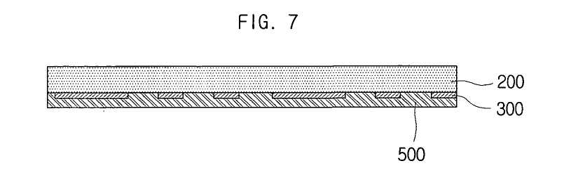

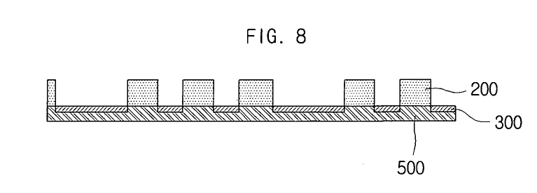

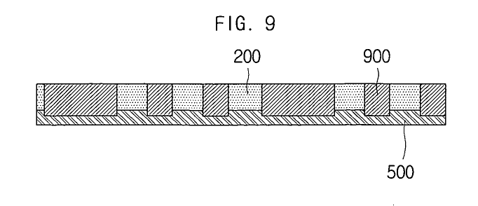

A negative photoresist refers to a type of resist in which portions that are not irradiated with light may be removed by developing. As illustrated in FIG. 2, a detachable protective film 202 may be formed over one side of the negative photoresist 200.

As illustrated in FIG. 3, a conductive ink may be ejected using an inkjet method onto the one side of the negative photoresist 200 to form the base pattern 300. The base pattern 300 can have substantially the same form as the circuit pattern 900, which is to be formed later. A conductive ink refers to an ink that contains conductive particles, such as of metal.

By forming the base pattern 300 using an inkjet method, fine-lined wiring can be formed with a simpler process, compared to the process for a photolithography method. The ability to quickly respond to demands in small-quantity large-variety products may also provide an advantage.

The ejecting of the conductive ink can be followed by an operation of sintering the conductive ink. The sintering may be performed under the appropriate conditions for sintering the conductive ink without deforming the negative photoresist 200.

Next, as illustrated in FIG. 4, one side of the negative photoresist 200 may be exposed (S200). Ultraviolet rays, for example, may be irradiated onto the one side of the negative photoresist 200, with the base pattern 300 acting as a mask. In this way, the portions of the negative photoresist 200 irradiated with the rays can be hardened.

Next, as illustrated in FIG. 5, an insulation layer may be attached to one side of the negative photoresist 200 such that the insulation layer is attached with the base pattern 300 (S300). The attaching of the insulation layer may include stacking a semi-cured (“B” stage) thermosetting resin 500 over one side of the negative photoresist 200 (S320). The thermosetting resin 500 can be, for example, prepreg.

Then, hot pressing may be performed for the thermosetting resin 500 and the negative photoresist, so that the base pattern 300 and the insulation layer may be attached (S340). As the semi-cured thermosetting resin 500 is pressed while heat is applied, the semi-cured thermosetting resin 500 can be cured, providing superior adhesion to the base pattern 300. In this way, the method of manufacturing a printed circuit board according to this embodiment can improve adhesion between the circuit pattern 900 and the insulation layer.

The attaching of the insulation layer may also be performed by attaching an insulation layer, which has an adhesive layer formed on one side, to one side of the negative photoresist. The material used for the insulation layer may be varied according to the usage of the printed circuit board. For example, if a flexible type printed circuit board is manufactured, the insulation layer may contain polyester or polyimide, while an adhesive layer, such as of epoxy resin, may be applied on one side to provide adhesion to the base pattern.

Next, the negative photoresist 200 may be developed such that the base pattern 300 is uncovered (S400). As illustrated in FIGS. 6 and 7, the negative photoresist 200 may first be turned upside down, and the detachable protective film 202 formed on the other side of the negative photoresist 200 may be stripped, to open the other side of the photoresist, of which certain portions will be selectively removed. After the other side of the negative photoresist 200, on which the base pattern 300 is not formed, is uncovered, the non-hardened portions may be removed by dissolving in a developing liquid.

As illustrated in FIG. 8, the portions of the negative photoresist 200 at which the base pattern 300 is formed may be selectively removed, to uncover the base pattern 300. Consequently, the negative photoresist 200 around the base pattern 300 may form a wall-like structure that serves as a kind of guide.

Next, conductive ink may be ejected over the base pattern 300 to form the circuit pattern 900 (S500). The conductive ink may be ejected repeatedly over the base pattern 300 using an inkjet method, to form the circuit pattern 900. The circuit pattern 900 can be regarded as an integrated form of the base pattern 300 and the subsequently ejected conductive ink.

As illustrated in FIG. 9, the negative photoresist 200 surrounding the base pattern 300 may serve as a guide, so that the circuit pattern 900 may be formed with a uniform width and a desired thickness.

As described above, in a method of manufacturing a printed circuit board according to this embodiment, a semi-cured thermosetting resin 500 may be attached to the base pattern 300, to ensure adhesion between the circuit pattern 900 and the insulation layer. Also, by forming a guide structure around the base pattern 300 using a negative photoresist 200 and then ejecting the conductive ink to form the circuit pattern 900, a circuit pattern 900 may be obtained to a thickness that provides high reliability.

As such, certain embodiments of the invention as set forth above can be utilized, in the manufacture of a printed circuit board, to increase the thickness of the circuit pattern and strengthen the adhesion between the circuit pattern and the insulation layer.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing a printed circuit board, the method comprising:
forming a base pattern over one side of a negative photoresist;
exposing the one side;
attaching an insulation layer on the one side;
developing the negative photoresist such that the base pattern is uncovered; and
forming a circuit pattern over the base pattern.

2. The method of claim 1, wherein the forming of the base pattern comprises:
ejecting conductive ink over the one side to form the base pattern.

3. The method of claim 1, wherein the attaching of the insulation layer comprises:
stacking a semi-cured thermosetting resin over the one side; and
hot-pressing the thermosetting resin and the negative photoresist.

4. The method of claim 1, wherein the insulation layer contains polyester or polyimide.

5. The method of claim 1, wherein the forming of the circuit pattern comprises:
ejecting conductive ink over the base pattern to form the circuit pattern.
